(19) United States
(12) Patent Application Publication
(10) Pub. No.: US 2015/0108662 A1
(43) Pub. Date: Apr. 23, 2015

(54) PACKAGE MODULE WITH OFFSET STACK DEVICE

(71) Applicant: Innovative Turnkey Solution Corporation, Hsinchu City (TW)

(72) Inventor: Shih-Chi CHEN, Hsinchu City (TW)

(73) Assignee: Innovative Turnkey Solution Corporation, Hsinchu City (TW)

(21) Appl. No.: 14/092,421

(22) Filed: Nov. 27, 2013

(30) Foreign Application Priority Data
Oct. 21, 2013 (TW) 102137969

(51) Int. Cl. H01L 25/065

(52) U.S. Cl. CPC H01L 25/0652
USPC 257/777

(57) ABSTRACT

A package module with offset stacked device is provided which includes a group of stacked device, a carrier and a substrate. The group of stacked device is offset stacked to dispose in the carrier and the substrate is disposed on the bottom of the carrier. A plurality of electric connections is disposed on the surface substrate that is opposite to the carrier. A plurality of outer connections on another surface of the substrate is electrically connected with the plurality of electric connections. The group of the stacked device is electrically connected with the carrier by the connecting the plurality of metal connections and the pads. The plurality of metal connections is extended to the bottom of the carrier to form another metal connection to electrically connect with the electric connection on the substrate.

### FIELD OF THE INVENTION

The present invention relates to a package module with an offset stacked device, and in particular to a module of packaging a stacked device with a plurality of chips therein.

### BACKGROUND OF THE INVENTION

Modern life is inseparable from the large number of electronic products, and therefore the demand for the semiconductor industry, more and more, the semiconductor industry will continue to evolve to meet the market demand for a variety products, the most common needs of hope is that the product with better functionality is manufactured by the smaller space the same or even better product functionality.

The stacked chip package is a package method for reducing the space of the package product, the package method arranges a number of different dies with different function into a package module, in addition to achieve functional integration purposes, the space of circuit board can effectively save, and the space occupied by the chip can also be reduced, so as to reduce overall manufacturing costs. In addition, the circuit distance between the plurality of dies in the package can be short to provide the better electrical performance, and the signal propagation is interfered in the circuit can be effectively reduced.

Currently, the mostly package method of the stacked chip package is memory chip package, such as flash memory and static random access memory are stacked each other. The part of the communications chip also utilizes the stacked wafer level package, for example, the base frequency, flash memory and static random access memory chips, which are configured into a single package.

However, the present stacked chip package still has some drawbacks, such as a wafer are stacked in each other processes, because the chip includes a lots of pads thereon, so as to the electric contacts between the wafer substrate (substrate) and the substrate is difficult, and thus yield is to be reduced. Furthermore, in order to enhance the connection between the wafers, the most common way is to increase the encapsulation process between the wafers, however, the excessive encapsulation glue will increase the thickness of the overall packaging products, and the reliability of the package product is also reduced. In addition, also, it is difficult process to bonding the metal wires on the stacked wafers. In addition, when the packaged product is assembled to other electronic device such as circuit board, which needs the alignment to align the joint and the pads, such that the cost of packaging is to be increased. For the above disadvantages, there is a need for improvement.

### SUMMARY OF THE INVENTION

In order to solve the aforementioned drawbacks, the present invention provides a package module with an offset stacked device by the way of the three-dimensional carrier design to simply the stacked package device and to improve the reliability of the package product.

According to above object, the present invention provides a package module with an offset device which includes a carrier having a first surface and a second surface opposite to the first surface, a recess is formed in the first surface and an edge around the recess, the a first chip arrangement region is formed in the recess and a plurality of first metal connections is disposed on a bottom of the recess. A first platform is disposed adjacent to one side of the first chip arrangement region to allow a first recess wall that is disposed between the first platform and the first chip arrangement region and the plurality of first metal connections is exposed. The height of the first platform is higher than that of the first chip arrangement region. A plurality of second metal connections is disposed on the first platform, in which each the plurality of first metal connections is corresponding to one of the plurality of second metal connections, and each the plurality of corresponded first metal connections is electrically connected with the plurality of corresponded second metal connections through a plurality of first metal wires. A first chip having a top and a bottom and a plurality of first pads is disposed on the bottom of the first chip. The first chip is flipped and disposed on the first chip arrangement region to allow the plurality of first pads that is electrically connected with the plurality of first metal connections. A second chip having a top and a bottom and a plurality of second pads is disposed on the bottom of the second chip. The second chip is flipped on the top of the first chip to allow the plurality of second pads that is electrically connected with the plurality of second metal connections on the first platform and the portion top of the first chip is exposed. A glue is filled in the recess of the carrier to encapsulate the exposed top of the first chip and the top of the second chip, in which each the plurality of second metal connections is further electrically connected with a plurality of second metal connections, the plurality of second metal wires is extended from the first platform of the carrier to the edge on the first surface. Each the plurality of second metal wires on one end of the edge of the first surface is to form a plurality of third metal connections.

The present invention further provides a package module with an offset stacked device, which includes a carrier having a first surface and a second surface opposite to the first surface. A recess having a first surface and a first chip arrangement region is disposed in the recess. A plurality of first metal connections is disposed on the bottom of the recess. A first platform is disposed on one side of the first chip arrangement region to allow a first recess wall that is disposed between the first platform and the first chip arrangement region and the plurality of first metal connections is exposed. A height of the first platform is higher than that of the first chip arrangement region and a plurality of second metal connections is disposed on the first platform, in which each the plurality of first metal connections is corresponding to one of the plurality of metal connections and the plurality of corresponded first metal connections is electrically connected with each the plurality of corresponded second metal connections by the plurality of first metal wires. A first chip having a top and a bottom and a plurality of first pads is disposed on the bottom of the first chip. The first chip is flipped on the first chip arrangement region to allow the plurality of first pads is electrically connected with the plurality of first metal connections. A second chip having a top and a bottom and a plurality of second pads is disposed on the bottom of the second chip. The second chip is flipped on the top of the first chip to allow the plurality of second pads is electrically connected with the plurality of second metal connections on the first platform and the top of the portion first chip is exposed. A glue is filled in the recess of the carrier to encapsulate the exposed top of the first chip and the top of the second chip, in which the portion plurality of first metal connections is further electrically connected with the plurality of second metal wires and the remaining of the plurality of second metal connections is further electrically connected with the plurality of third metal connections. Each the plurality of second metal wires is extended from the first chip arrangement region to the edge of the first surface and the plurality of second metal connections on one end of the edge of the first surface is to form a plurality of third metal connections. Meanwhile, each the plurality of third metal connections is extended from the first platform to the edge of the first surface and the plurality of third metal wires on one end of the edge of the first surface is to form a plurality of fourth metal connections.

The present invention also provides a package module with an offset stacked device, which includes a carrier having a first surface and a second surface opposite to the first surface. A recess is formed on the first surface and a first chip arrangement region is disposed on the recess. A plurality of first metal connections is disposed on a bottom of the recess. A first platform is disposed on one side of the first chip arrangement region to allow a first recess wall that is disposed between the first platform and the first chip arrangement region and the plurality of first metal connections is exposed. A height of the first platform is higher than that of the first chip arrangement region and a plurality of second metal connections is disposed on the first platform, in which each the plurality of first metal connections is corresponding to one of the plurality of second metal connections and the plurality of corresponded first metal connections is electrically connected with the plurality of corresponded second metal connections by the plurality of first metal wires. A first chip having a top and a bottom and a plurality of first pads is disposed on the bottom of the first chip. The first chip is flipped on the first chip arrangement region to allow the plurality of first pads that is electrically connected with the plurality of first metal connections. A second chip having a top and a bottom and a plurality of second pads on the bottom of the second chip. The second is flipped on the top of the first chip to allow the plurality of second pads that is electrically connected with the plurality of second metal connections on the first platform and the top of portion first chip is exposed. A glue is filled in the recess of the carrier to encapsulate the exposed top of first chip and the top of the second chip, in which the portion the plurality of first metal connections is further electrically connected with the plurality of second metal wires and the plurality of second metal connections is electrically connected with the remaining of the plurality of metal connections that is further electrically connected with the plurality of third metal wires. Each the plurality of second metal wires is extended to the edge of the first surface from the first chip arrangement region, the plurality of second metal wires on one side of the edge of the first surface is to form a plurality of third metal connections. Meanwhile, each the plurality of third metal wires is extended to the edge of the first surface from the first platform and the plurality of metal wires on one side of the edge of the first surface is to form a plurality of metal connections.

The present invention further provides a package module with an offset stacked device, which includes a carrier having a first surface and a second surface opposite to the first surface. A first surface having a recess and an edge around the recess. A first chip arrangement region is disposed on the recess and a plurality of first metal connections is disposed on a bottom of the recess. A first platform is disposed on one side of the first chip arrangement region and the plurality of first metal connections is exposed. A height of the first platform is higher than that of the first chip arrangement region. A first recess wall is disposed between the first platform and the first chip arrangement region and angle between the first recess wall and the first chip arrangement region is in range from 90 degree to 135 degree. A second recess wall is disposed between the first surface and the first platform and the angle between the second recess wall and the first platform is in range from 90 degree to 135 degree. A third recess wall is disposed between the edge and the first chip arrangement region and the angle between the third recess wall and the first chip arrangement region is in range from 90 degree and 135 degree. A plurality of second metal connections is disposed on the first platform, and each the plurality of first metal connections is corresponding to one of the plurality of second metal connections and the plurality of corresponded first metal connections is electrically connected with the plurality of corresponded second metal connections by a plurality of first metal wires. The plurality of first metal wires is disposed on the first recess wall. A first chip having a top and a bottom and a plurality of first pads is disposed on the bottom of the first chip. The first chip is disposed on the first chip arrangement region to allow the plurality of first pads is electrically connected with the plurality of first metal connections. A second chip having a top and a bottom and a plurality of second pads is disposed on the bottom of the second chip. The second chip is flipped on the top of the first chip to allow the plurality of second pads that is electrically connected with the plurality of second metal connections on the first platform and the top of portion first chip is exposed. A glue is filled in the recess of the carrier to encapsulate the exposed top of the first chip and the top of the second chip, in which the plurality of first metal connections is extended to the edge of the first surface from the first platform of the carrier and the plurality of second metal wires on one edge of the first surface is to form a plurality of third metal connections.

According to the package module with an offset stacked device of the present invention, the stacked device module is combined with the carrier during the packaging process and is further combined the carrier with the substrate to accomplish the package module, and the carrier and the substrate can be performed via the standardized process by other manufactures to decrease the cost of the packaging can be decreased.

According to the package module with an offset stacked device of the present invention, the group of stacked device is disposed in the carrier after packaging process, such that the package module will not be affected by external substances, such that the reliability can be improved.

According to the package module with an offset stacked device of the present invention, the carrier and the substrate can be manufactured via the standardized process, such that the product size also can be standardized, and time required for the wire bonding and the alignment can be decreased, and the work efficiency for the packaged plant and the subsequent package application vendors can be increased.

### BRIEF DESCRIPTION OF THE DRAWINGS

The present invention will be apparent to those skilled in the art by reading the following description of a preferred embodiment thereof with reference to the drawings, in which:

FIG. 1 is a top view of the carrier in accordance with present invention;

FIG. 2 is a first embodiment of the top view of the carrier in accordance with the present invention;

FIG. 3 is a vertical view of the first chip in accordance with the present invention;

FIG. 4A shows a cross-sectional view of a first embodiment of a package module with an offset stacked device in accordance with the present invention;

FIG. 4B is a cross-sectional view of another embodiment of the package module with an offset stacked device in accordance with the present invention;

FIG. 5A is a top view of substrate in accordance with the present invention;

FIG. 5B is vertical view of the substrate in accordance with the present invention;

FIG. 6 is a second embodiment of a cross-sectional view of the package module with an offset stacked device in accordance with the present invention;

FIG. 7A is a third embodiment of to the top view of the substrate in accordance with the present invention;

FIG. 7B is a third embodiment of a vertical view of substrate in accordance with the present invention;

FIG. 8 is a top view of the third embodiment of the substrate in accordance with the present invention;

FIG. 9 is a third embodiment of a cross-sectional view of the package module with an offset stacked device in accordance with the present invention;

FIG. 10A is fourth embodiment of a top view of the substrate in accordance with the present invention;

FIG. 10B is a fourth embodiment of the vertical view of the substrate in accordance with the present invention; and

FIG. 11 is a fourth embodiment of the cross-sectional view of the package module with an offset stacked device in accordance with the present invention.

### DETAILED DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

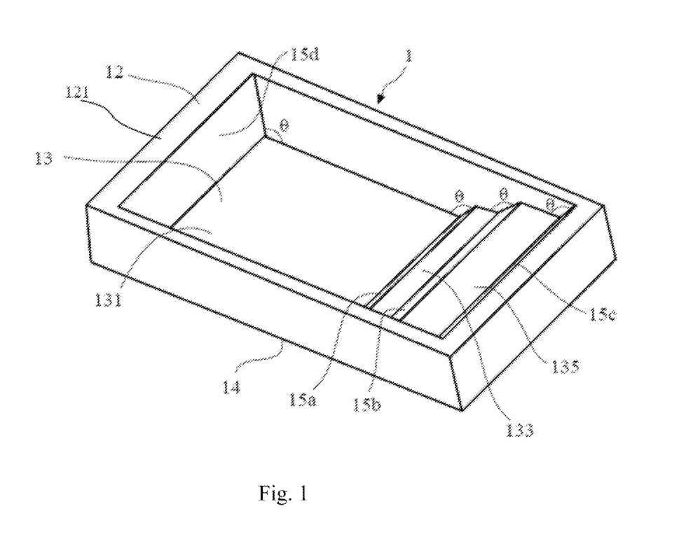

Please refer to FIG. 1. FIG. 1 is a top view of the carrier of the present invention. In FIG. 1, the carrier 1 is formed by polymer injection molding method, and the material of the polymer is polyimide ammonium. The carrier 1 having a first surface 12 and a second surface 14 opposite to the first surface 12. A recess 13 is disposed in the first surface 12 and an edge 121 around the recess 13. The bottom of the recess 13 is a first chip arrangement region 131. A first platform 133 and a second platform 135 are disposed on one side in the recess 13 respectively. The first platform 133 is disposed adjacent to the first chip arrangement region 131 and the height of the first platform 133 is higher than that of the first chip arrangement region 131. In one embodiment, the height of the first platform 133 can be designed as the same height of the chip which is to be packaged. Then, the second platform 135 is disposed adjacent to the first platform 133. In one embodiment, the height of the second platform 135 is higher than that of the first platform 133. In one embodiment, the height of the second platform 135 can be designed as same that of the chip which is to be packaged. According to aforementioned, the first chip arrangement region 131, the first platform 133 and the second platform 135 can be regards as a stepped structure on one side of the recess 13. In addition, the recess wall 15a between the first chip arrangement region 131 and the first platform 133, the recess wall 15b between the first platform 133 and the second platform 135, the recess wall 15c between the second platform 135 and the first surface 12, and the recess wall 15d between the first surface 12 and the first chip arrangement region 131 are inclined. The angle between each recess wall and each plane is denote as θ, in which the angle θ is in range from 90 degree to 135 degree, 90□≦0≦135□, that is, each recess wall 15a, 15b, 15c and 15d are either vertical or inclined. It is note to illustrate that the angle between each recess wall 15a, 15b, 15c, 15d and each plane of the recess 13 is not limited herein. The purpose for disposing the recess wall 15a, 15b, 15c, and 15d is to assist the location and the alignment of the chip while the chip is being packaged onto the carrier 1.

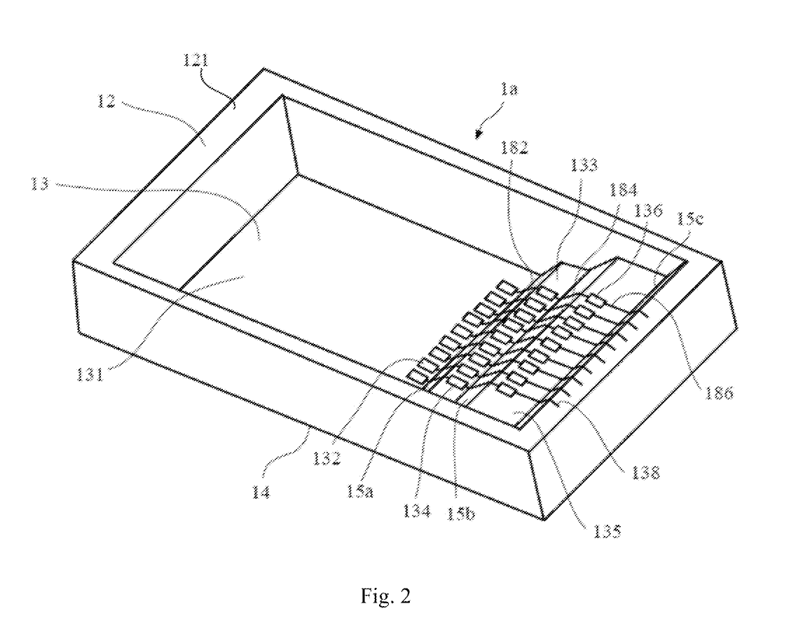

Next, please refer to FIG. 2. FIG. 2 is a top view of the carrier the present invention. First, as shown in FIG. 2, a plurality of metal connections 132 is disposed on the first chip arrangement region 131 of the carrier 1a and adjacent to one side of the first platform 133. The plurality of metal connections 134 is disposed on the first platform 133 and a plurality of metal connections 136 is also disposed on the second platform 135. Meanwhile, each number of the plurality of metal connections 134 is identical to the each number of the plurality of metal connections 136. Each the plurality of metal connections 132 is electrically connected with each the plurality of metal connections 134 through the plurality of metal wires 182, and each the plurality of metal connections 134 is electrically connected with each the plurality of metal connections 136 through the plurality of metal wires 184. Each the plurality of metal connections 136 is further electrically connected with the plurality of metal wires 186, in which the plurality of metal wires 186 is extended to edge 121 of the first surface 12 of the carrier 1a to electrically connect with the plurality of metal connections 138. The plurality of metal connections 138 is disposed on any place of the edge 121 of the first surface 12 whose height is higher than that of the second platform 135. In one embodiment, the plurality of metal connections 138 is disposed around the recess 13 in a neatly arrangement and the arrangement of the plurality of metal connections 138 on the first 12 is not to be limited.

Then, the formation of the plurality of metal connections 182, 184, 186 includes the location of the plurality of metal wires 182, 184, 186 is first formed by laser engraving and then electroplating. For example, the recess wall 15a between the plurality of metal connections 132 and the plurality of metal connections 143 is engraved to form a location of plurality of metal wires 182 and then a plurality of metal wires 182 is formed by plating. In one embodiment, the recess wall 15a, 15b, and 15c are inclined respectively such that the plating of the plurality of metal wires 182, 184, and 186 can be effectively improved.

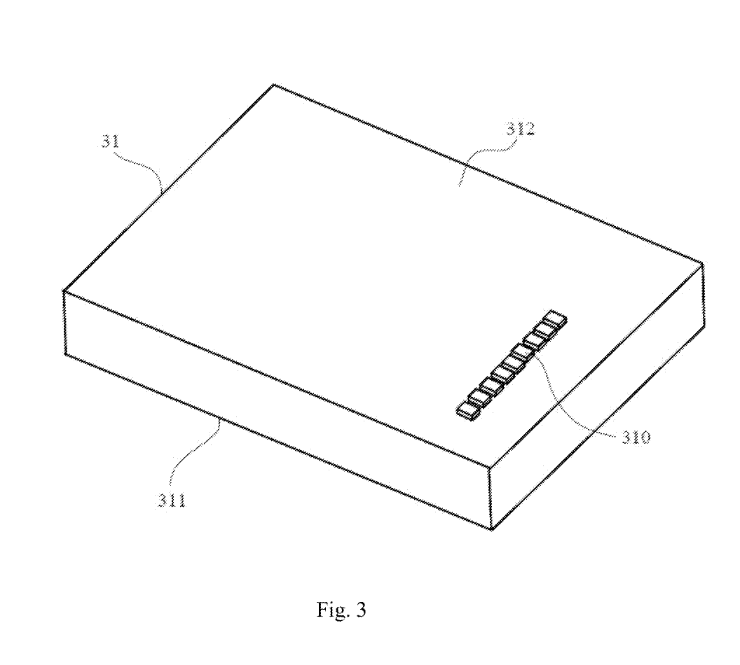

Next, please refer to FIG. 3. FIG. 3 is a vertical view of the first chip. As shown in FIG. 3, the first chip 31 is formed by cutting the wafer after accomplishing the semiconductor manufacturing. The first chip 31 having a top 311 and a bottom 312 opposite to the top 311. A plurality of pads 310 is disposed on the bottom 312 of the first chip 31. In this invention, the first chip 31 can be a memory chip, in particular to a NAND flash memory. When the first chip 31 is NAND flash memory, there are 48 pads on the bottom 312 of the first chip 31. Oppositely, there are 48 metal connections 132, 48 metal connections 134, 48 metal connections 136 and 48 metal connections 138 are disposed in the carrier 1, and there will be a corresponding number of plurality of metal wires 182, 184 and 186, in which the each plurality of metal connections is electrically connected with each other via the plurality of metal wires. However, the number of the pads 310 on the first chip 31 is not to be limited, similarly, the number of the metal connections 132, 134, 136, 138 and the different number of the plurality of metal wires 182, 184, and 186 are corresponding to the different number of the plurality of pads 310 respectively.

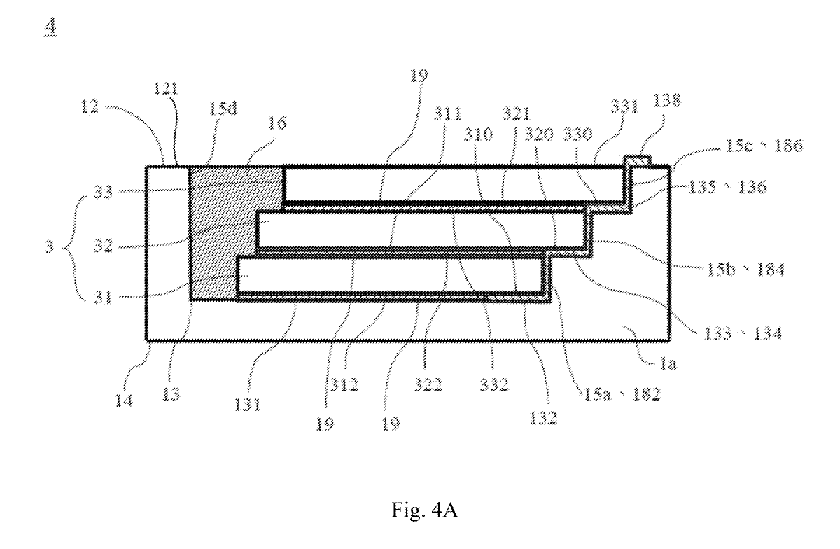

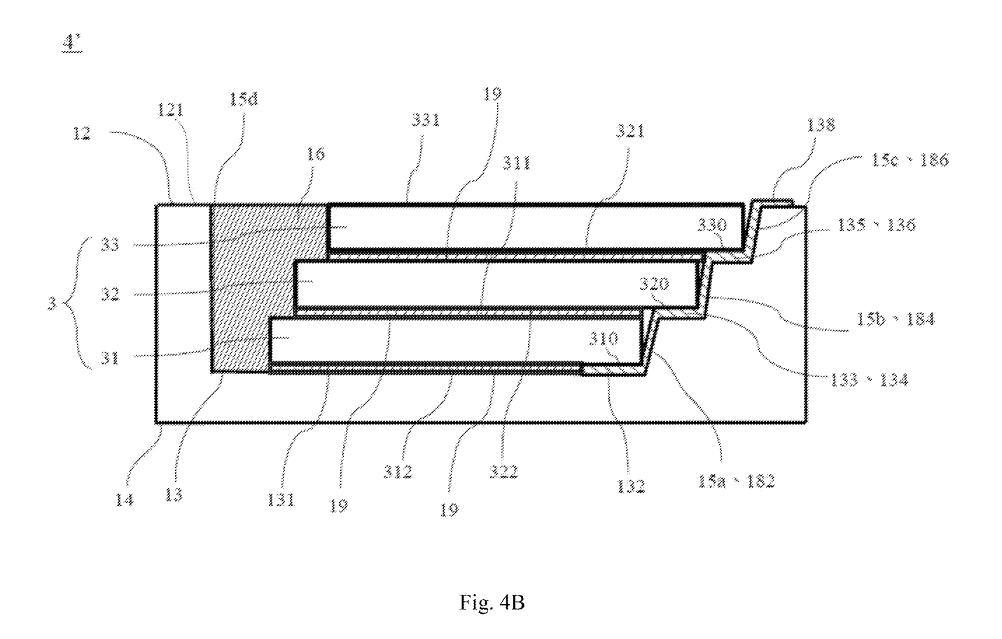

Next, please refer to FIG. 4A. FIG. 4A shows a cross-sectional view of a first embodiment of a package module with an offset stacked device of the present invention. As shown in FIG. 4A, the package module with an offset stacked device 4 includes a carrier 1a and a group of stacked device 3 as shown in FIG. 2. The group of stacked device 3 is constructed by a first chip 31, a second chip 32 and a third chip 33 that are stacked in the recess 13 of the carrier 1a, in which the profile of the second chip 32 and the third chip 33 is similar to the first chip 32 in the FIG. 3, and thus it is not to be described herein and the connecting relationship between the group of stacked device 3 and the recess 13 will be described in detail in subsequently specification.

First, a buffer material 19 is formed above the first chip arrangement region 131, and the first chip 31 is disposed in the first chip arrangement region 131, in which the plurality of pads 310 on the bottom of the first chip 31 and the first chip 31 is flipped to allow the plurality of pads 310 on the bottom 312 is electrically connected with the plurality of the metal connections 132, such that the buffer material 19 is disposed between the first chip 31 and the first chip arrangement region 131. The material of the buffer material 19 can be a paste. Then, a buffer material 19 is formed on the top 311 of the first chip 31 and the second chip 32 is flipped to allow the bottom of the second chip 32 that is electrically connected with the top 311 of the first chip 31 and the plurality of pads 320 on the bottom 322 of the second chip 32 is electrically connected with the plurality of metal connections 134 on the first platform 133. Meanwhile, the buffer material 19 is disposed between the second chip 21 and the first chip 31. In addition, when the bottom 322 of the second chip 32 is stacked on the top 311 of the first chip 31, the portion top 311 of the first chip 31 is not encapsulated by the second chip 32. Next, the buffer material 19 is formed above the top 321 of the second chip 32 and the bottom 332 of the third chip 33 is flipped to contact the top 321 of the second chip 32 to allow the plurality of pads 330 on the bottom 332 of the third chip 33 that is electrically connected with the plurality of metal connections 136 on the second platform 135, and the buffer material 19 is disposed between the third chip 33 and the second chip 32. Furthermore, when the bottom 332 of the third chip 32 is stacked on the top 321 of the second chip 32, the portion top 321 of the second chip 32 is not to be covered by the third chip 33. Thus, when the plurality of chips is stacked in the carrier 1a, the plurality of chips will form a stepped structure on the opposite side of the first platform 133 and the second platform 135. In addition, it is emphasized that the top 331 of the third chip 33 of the stacked device 3 is not higher than that of the first surface 12 of the carrier 1a. As the abovementioned, the first chip 31, the second chip 32, and the third chip 33 is electrically connected with the carrier 1a by flipping method. In addition, due to the recess wall 15a, recess wall 15b, and recess wall 15c are vertical as shown in FIG. 4A, and each chip is disposed close to the recess wall by the location when the plurality of chips is packaged. In one preferred embodiment, as shown in FIG. 4B, the recess walls 15a, 15b, and 15c of the package module with an offset stacked device 4′ can be designed as the inclined with an angle θ, the chip can slide to the suitable location by the inclined surface of the recess wall 15a, 15b, and 15c even the error in the location for disposing the chip in the carrier 1a. In addition, in a preferred embodiment, alternatively, the glue 16 is filled in the recess 13 of the carrier 1a to encapsulate the exposed top 311 of the first chip 31, the exposed top 321 of the second chip 32 and the top of the third chip 33 after the plurality of chips is to form a group of stacked device 3 in the recess 13. In this embodiment, the glue 16 is epoxy. In one embodiment, the buffer material 19 has stickiness to combine the carrier 1a, the first chip 31, the second chip 32 and the third chip 33 better with each other.

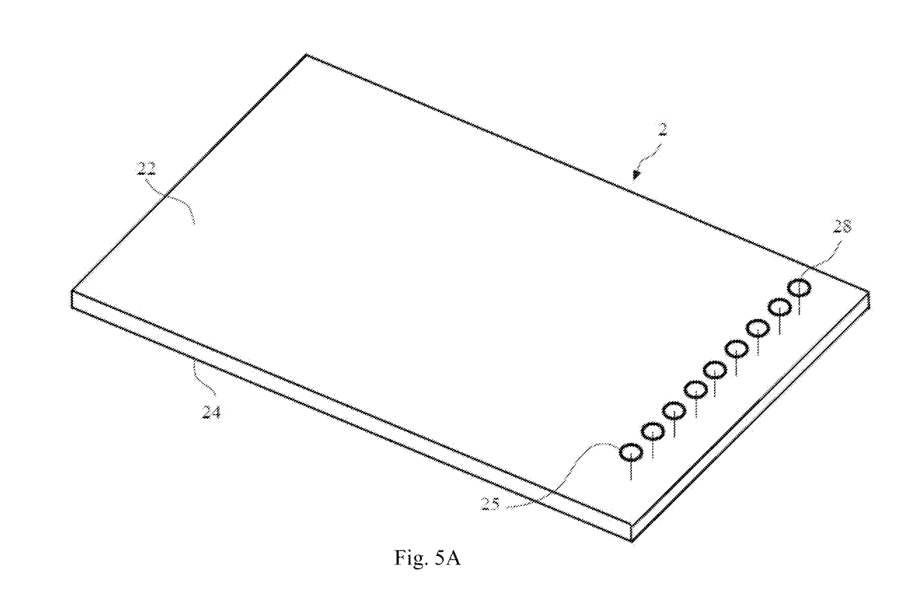

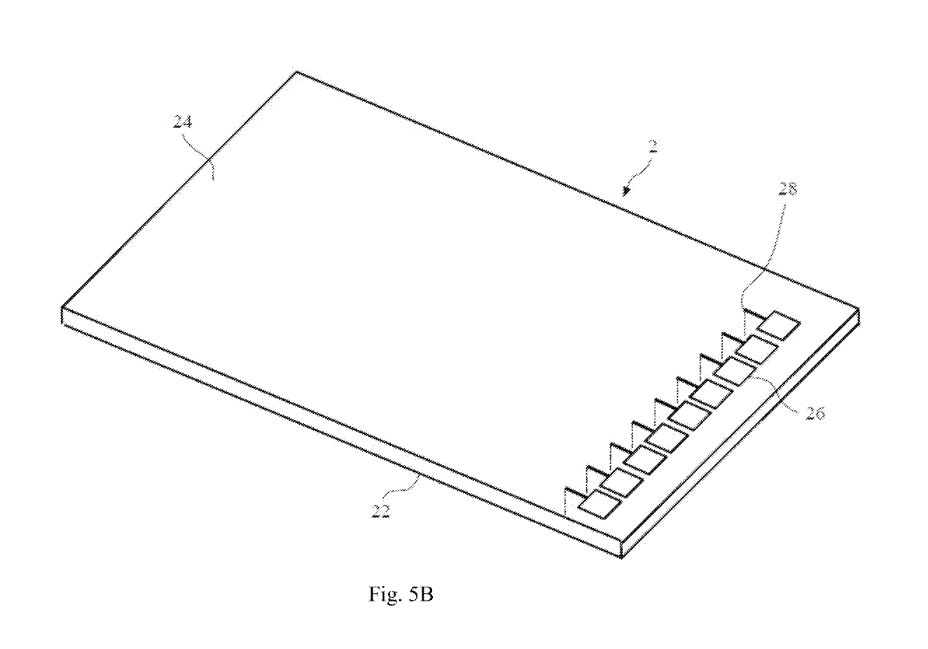

Next, please refer to FIG. 5A. FIG. 5A is a top view of substrate of the present invention. FIG. 5B is a vertical view of the substrate of the present invention. As shown in FIG. 5A, the substrate 2 having a third surface 22 and a fourth surface 24 opposite to the third surface 22, and a plurality of through holes 28 is passed through from the third surface 22 to the fourth surface 24. A plurality of electric connections 25 is disposed on the third surface 22 and each the plurality of electric connections 25 is extended to the fourth surface 24 via the plurality of through holes 28 of the substrate 2 to form a plurality of outer connections 26. The plurality of outer connections 26 is fan-out and neatly arranged as the arrangement of the FIG. 5B, but the arrangement of the plurality of outer connections 26 and the plurality of electric connections 25 are not limited respectively herein.

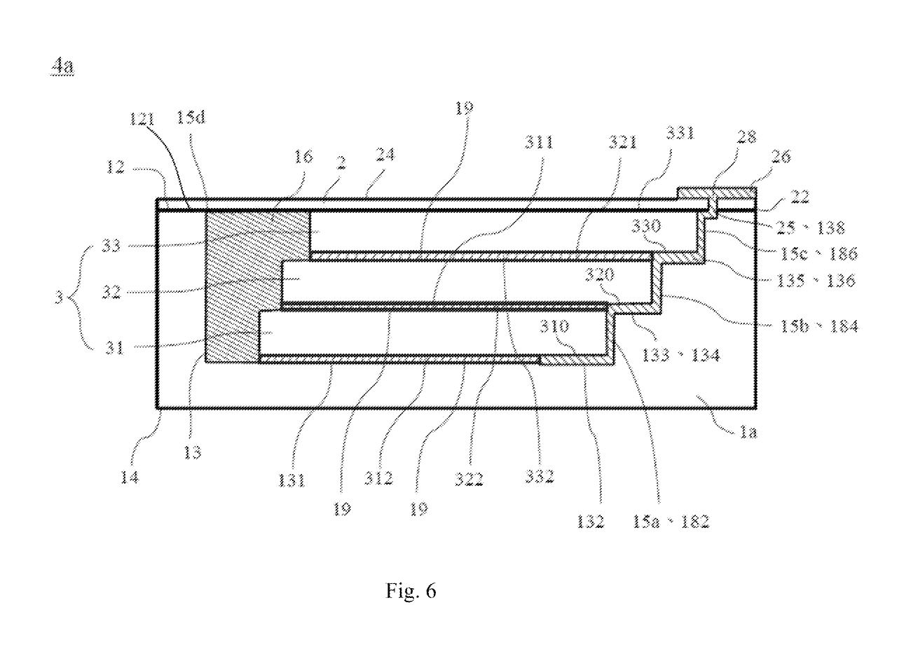

Please refer to FIG. 6. FIG. 6 is a second embodiment of a cross-sectional view of the package module with an offset stacked device of the present invention. As shown in FIG. 6, the first surface 12 of the carrier 1a of the package module with an offset stacked device 4 is contacted the third surface of the substrate 2 to form a package module with an offset stacked device 4a. the arrangement of the substrate 2 is that a group of the stacked device 3 is arranged in a recess 13 of the carrier 1a and a substrate 2 covered on the first surface 12 of the carrier 1a to allow the third surface 22 of the substrate 2 is contacted the first surface 12 of the carrier 1a, the joint between the first surface 12 of the carrier 1a and the third surface 22 of the substrate 2 is that each the plurality of metal connections 138 is contacted the plurality of electric connections 25 to allow each the plurality of metal connections 138 on the first surface 12 of the carrier 1a that is electrically connected with the plurality of electric connections 25 on the third surface 22 of the substrate 2. Obviously, to compare with the package module with an offset stacked device 4a, the package module with an offset stacked device 4 did not includes substrate 2 therein, and the package module with an offset stacked device 4 can electrically connect the connection (not shown) on the board (not shown) with the plurality of metal connections 138 on the edge 121 of the first surface 12 of the carrier 1a. Obviously, the connection (not shown) on the board must correspond to the plurality of metal connections 138. The different arrangement is required for when the plurality of metal connections 138 of the package module with an offset stacked device 4 needs to co-operate the different placement board (not shown), such that the carrier 1a cannot be modular production to increase the manufacture cost. In contrast to the package module with an offset stacked device 4a of present invention, changing the fan-out arrangement of the plurality of outer connections 26 on the substrate 2, the package module with an offset stacked device 4a can co-operate the different placement board (not shown) and the carrier 1a can be modular production to decrease the cost of the packaging.

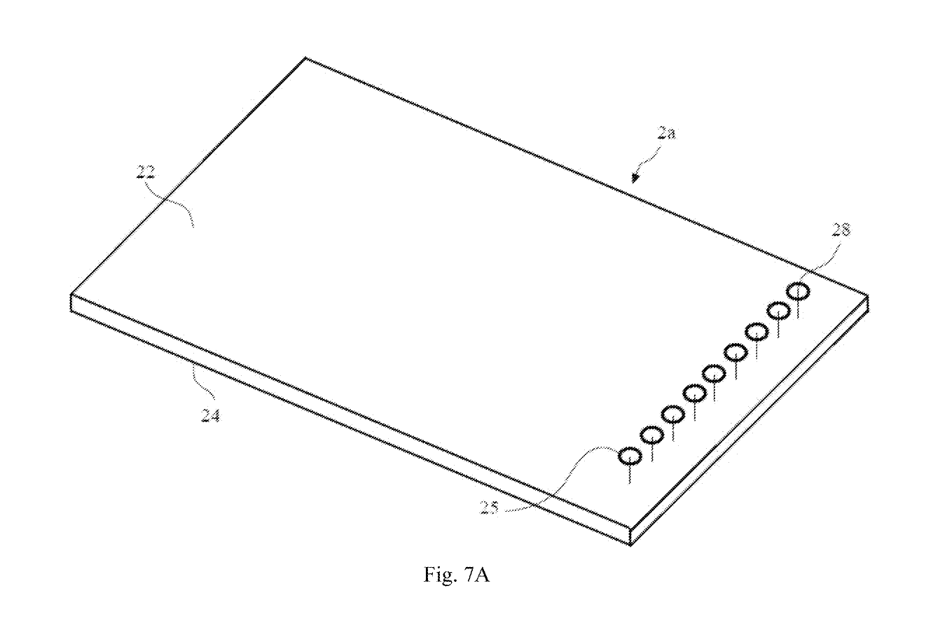

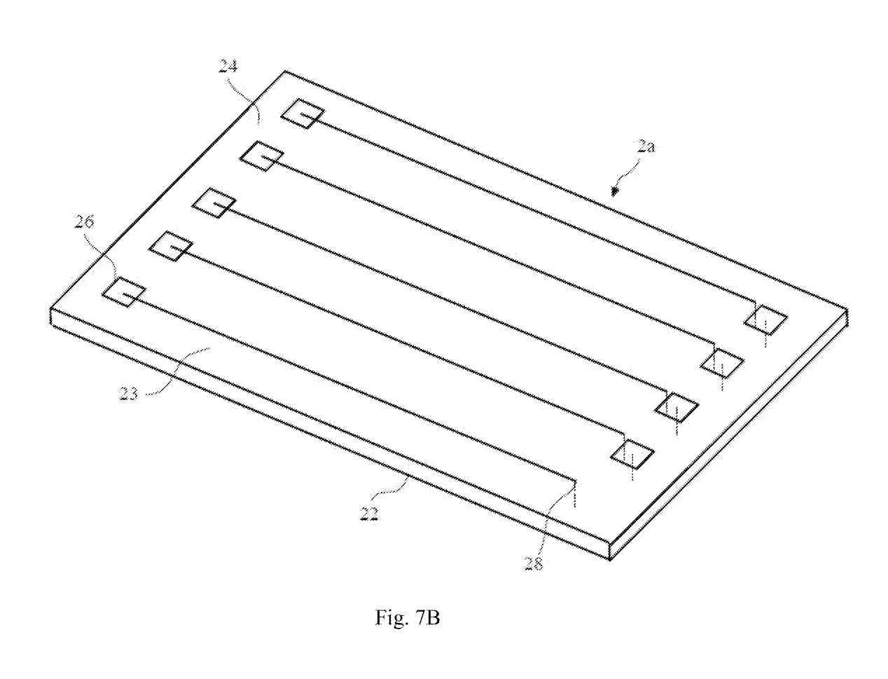

Then, please refer to FIG. 7A and FIG. 7B. FIG. 7A is a third embodiment of a top view of the substrate of the present invention and FIG. 7B is a third embodiment of the vertical view of the substrate of the present invention. As shown in FIG. 7A, the substrate 2a having a third surface 22 and a fourth surface 24 and a plurality of through holes 28 is passed through the third surface 22 to the fourth surface 24. The plurality of electric connections 25 is neatly arranged on the third surface 22 of the substrate 2a. The plurality of electric connections 25 is extended to the fourth surface of the substrate 2a through the plurality of through holes 28 and the plurality of metal wires 23 in the plurality of through holes 28 to form a plurality of outer connections 26 in a neatly arrangement. In addition, in one embodiment, as shown in FIG. 7B, the plurality of outer connections 26 on the fourth surface 24 can arrange in a fan-out arrangement by the plurality of arranged metal wires 23 such that the plurality of outer connections 26 is disposed toward the peripheral of the fourth surface 24 of the substrate 2 and the gap between the plurality of the outer connections 26 is increased. Meanwhile, the size of the plurality of the outer connections 26 is also increased. In another embodiment, because the substrate 2a is a multi-layers printed circuit board, the plurality of metal wires 23 can fan-out toward the peripheral of the fourth surface 24 or fan-out toward the peripheral from inside of the substrate 2.

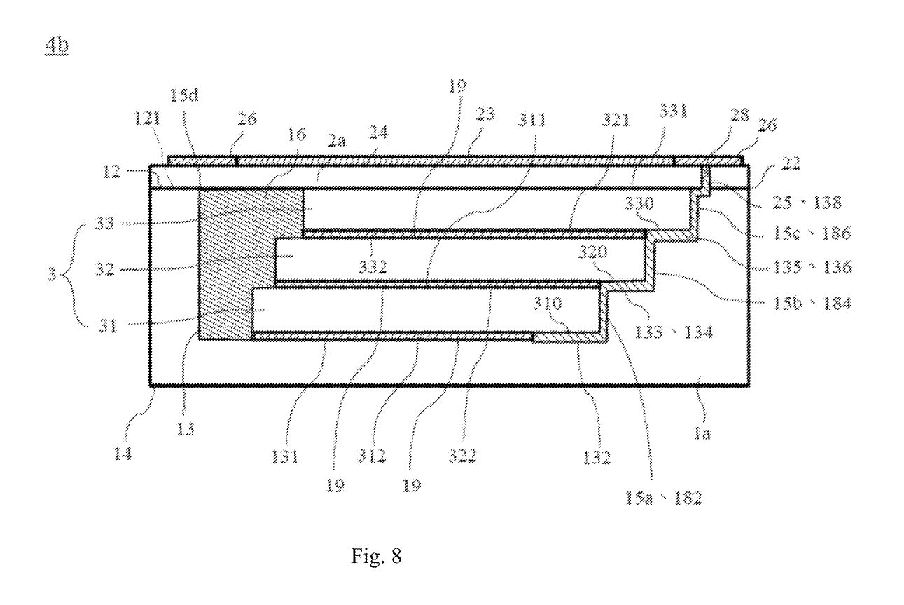

Then, please refer to FIG. 8. FIG. 8 is a third embodiment of the top view of the package module with an offset stacked device of the present invention. As shown in FIG. 8, the package module with an offset stacked device 34b includes a carrier 1a (as shown in FIG. 3), the substrate 2a and the group of the stacked device 3 (as shown in FIG. 7A and FIG. 7B). The location of each the plurality of electric connections 25 on the substrate 2a is relatively contacted a metal connection 138. The arrangement of other device of the package module with an offset stacked device 4b is similar to the package module with an offset stacked device 4, and it is not to be described in detail herein. After packaging, the package module with an offset stacked device 4b is electrically connected with the connection (not shown) on the board (not shown) by the plurality of outer connections 26 on the substrate 2a. In this embodiment, the configuration of the plurality of outer connections 26 is not dense and the manufacturing is more easily. Moreover, the carrier 1a can be packaged following above steps without the second platform 135. In other words, the structures of the package module 4, 4′, 4a and 4b with an offset stacked device can be different from the package modules shown in the FIG. 4A, FIG. 4B, FIG. 6 and FIG. 8 and the above advantages of the present invention are not to be affected.

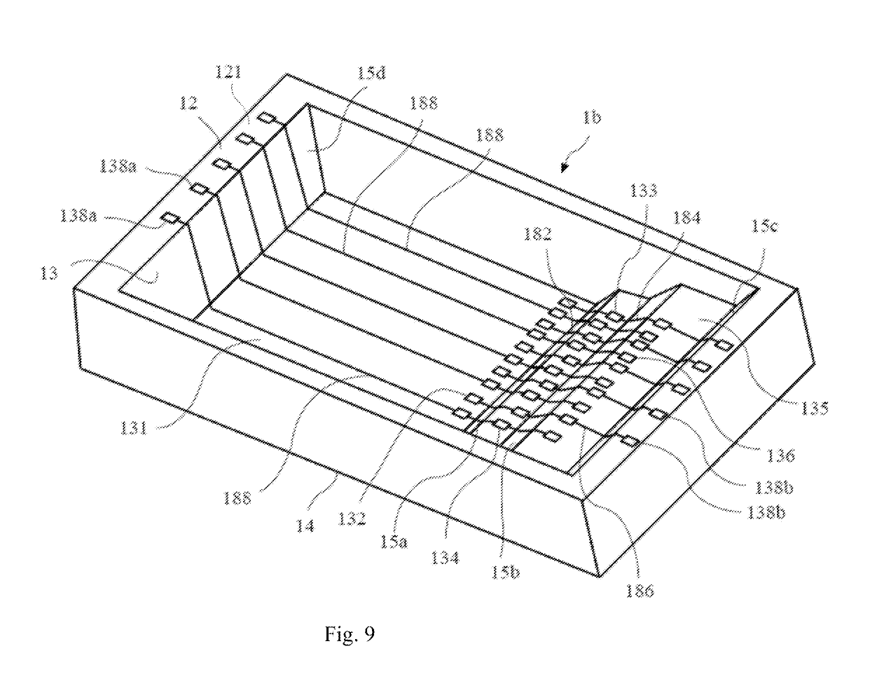

Please refer to FIG. 9. FIG. 9 is a fourth embodiment of the top view of the carrier of the present invention. As shown in FIG. 9, the carrier 1b is disposed on in the first chip arrangement region 131 and a plurality of metal connections 132 is disposed adjacent to one side of the first platform 133. The plurality of metal connections 134 is disposed on the first platform 133 and a plurality of metal connections 136 is also disposed on the second platform 135. The number of the plurality of metal connections 132, the number of the plurality of metal connections 134 and the number of the plurality of metal connections 136 are identical. In addition, each the plurality of metal connections 132 is electrically connected with each the plurality of metal connections 134 through the plurality of metal wires 182. Each the plurality of metal connections 134 is electrically connected with each the plurality of metal connections 136 through the plurality of metal wires 184, in which the portion of the plurality of metal connections 132 is further electrically connected with the plurality of metal wires 188. The plurality of metal wires 188 is extended from the first chip arrangement region 131 and the recess wall 15d to the edge 121 of the first surface 12 to electrically connect with the plurality of metal connections 138a, and the rest portion of the plurality of metal connections 136 is electrically connected with the plurality of metal connections 132 that is further electrically connected with the plurality of metal wires 186. The plurality of metal wires 186 is extended from the second platform 135 and the recess wall 15c to the edge 121 of the first 121 to electrically connect the plurality of metal connections 138b. In one embodiment, the plurality of metal connections 138a, 138b are disposed on the peripheral of the recess 13 respectively. The formation of the plurality of metal wires 182, 184, 186 and 188 are similar as FIG. 2 and it is not described in detail herein. In one embodiment, the recess walls 15a, 15b, 15c and 15d are inclined, such that the plating of the plurality of metal wires 182, 184, 186, 188 can be improved easily. In this embodiment, the gap between each the plurality of metal wires 186 can be increased such that the manufacture can be easier. Similarly, the arrangement of each the plurality of metal wires 188, each the plurality of metal wires 138a and each the plurality of metal connections have the same advantages.

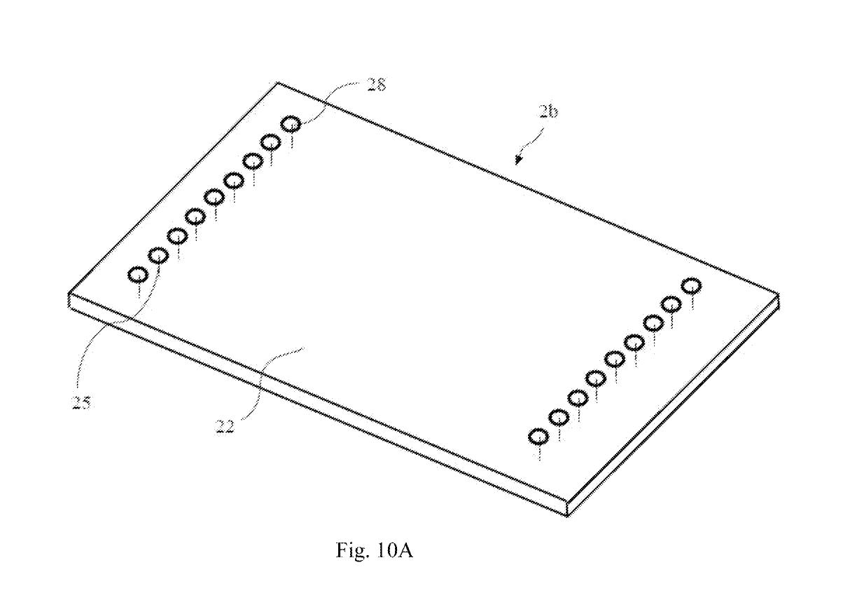

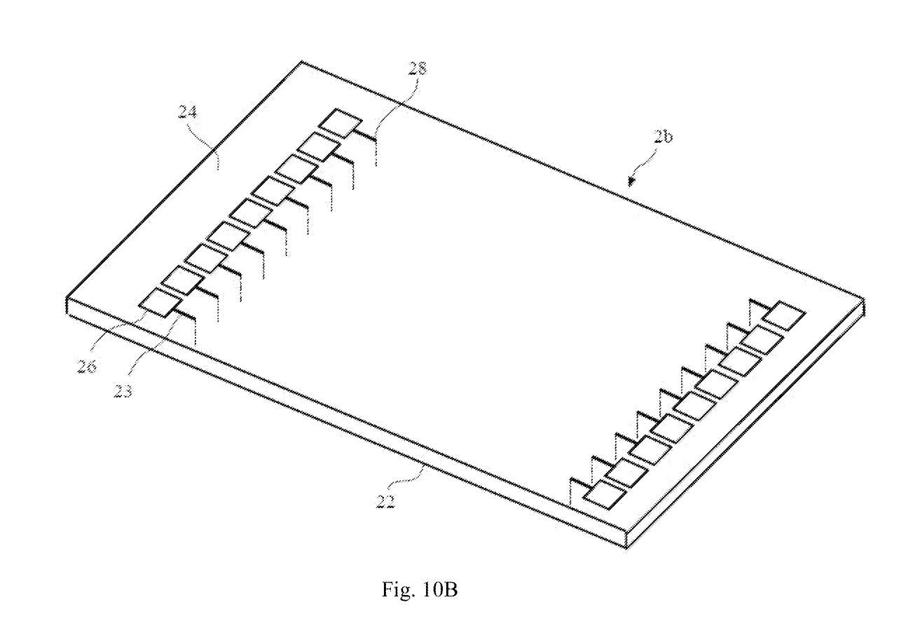

Please refer to FIG. 10A and FIG. 10B. FIG. 10A is a fourth embodiment of a top view of the substrate of the present invention and FIG. 10B is a fourth embodiment of the vertical view of the substrate of the present invention. As shown in FIG. 10A and FIG. 10B, the substrate 2b having a third surface 22 and a fourth surface 24 opposite to the third surface 22 and a plurality of through holes 28 is passed through the third surface 22 to the fourth surface 24. A plurality of electric connections 25 is formed on the third surface 22 of the substrate 2b and each the plurality of electric connections 25 is extended to the fourth surface 24 through the plurality of through holes 28 to form a plurality of outer connections 26. The plurality of outer connections 26 on the fourth surface 24 is arranged in fan-out arrangement by the plurality of arranged metal wires 23 to allow the plurality of outer connections 26 that is disposed on the peripheral of the fourth surface 24 of the substrate 2, such that the arrangement of the plurality of outer connections 26 as shown in FIG. 10B.

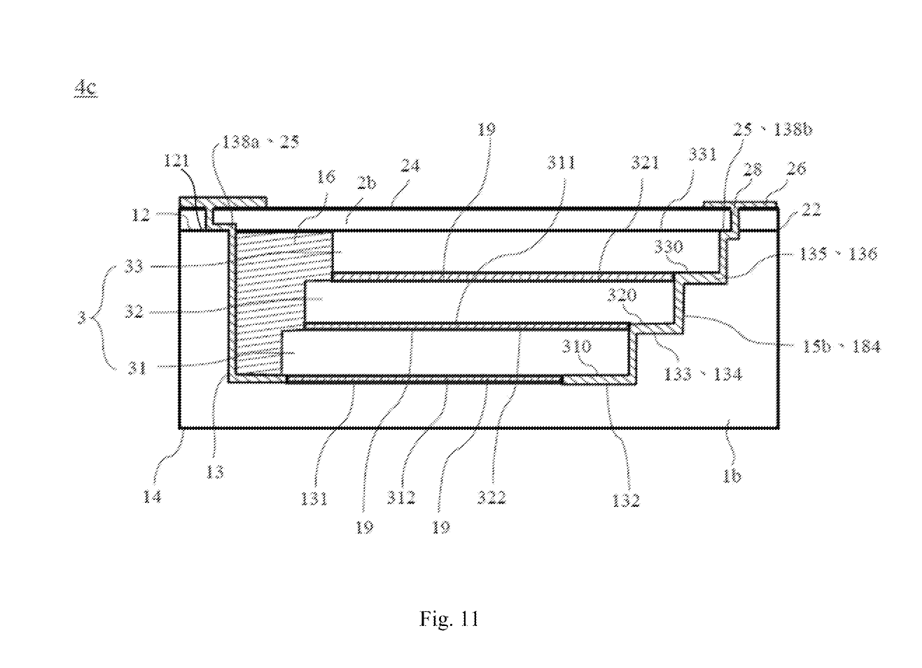

Then, please refer to FIG. 11. FIG. 11 is a fourth embodiment of cross-sectional view of the package module with an offset stacked device of the present invention. As shown in FIG. 11, the package module with an offset stacked device 4b includes a carrier 1b (as shown in FIG. 9), the substrate 2 and the group of the stacked device 3 (as shown in FIG. 10A and FIG. 10B). In the package module with an offset stacked device 4, the arrangement of the group of stacked device 3 is similar to the package module with an offset stacked device 4, and it is not to be described in detail herein. The third surface 22 of the substrate 2 is contacted the first surface 12 of the carrier 1b to allow each the plurality of the electric connections 25 on the third surface 24 is relatively contacted each the plurality of the metal connections 138a and each the plurality of metal connections 138b on the first surface 12, such that the package module with an offset stacked device 4b is electrically connected with the connection (not shown) on the board (not shown) by the plurality of outer connections 26 on the substrate 26. In addition, the package module with an offset stacked device 4b did not includes the substrate 2 therein to form another package module which can electrically connect the connection (not shown) on the board (not shown) by the plurality of metal connections 138a, 138b on the edge 121 of the first surface 12 of the carrier 1b. Moreover, the carrier 1b can be packaged following above steps without the second platform 135. In other words, the structures of the package module 4c with an offset stacked device can be different from the package modules shown in the FIG. 11 and the above advantages of the present invention are not to be affected

The number of the platforms is not limited in the carriers 1, 1a, and 1b of the present invention. According to the requirement, beside the first platform 133 and the second platform 124, the carriers 1, 1a, 1b also can add the third platform (not shown), the fourth platform (not shown) and so on, to allow the plurality of chips that can be packaged in the carriers 1, 1a, and 1b. Similarly, the number of the chips in the group of stacked device 3 is also not to be limited, and types and size for the first chip 31, the second chip 32 and the third chip are also not to be limited, which can have the same or different types and same size or different size.

The carriers 1, 1a, and 1b and the substrate 2, 2a, and 2b can be set via the standardization process and manufactured by the outside packaging factory manufacturers which can effectively reduce the production cost. The size of the package production can also be standardized by the standardized setting to increase the efficiency of the package vendor and the vendor which using the packaging product. Meanwhile, the group of stacked device 3 is disposed in the carriers 1, 1a, and 1b completely to increase the reliability of the package production.

Although the present invention has been described with reference to the preferred embodiment thereof, it is apparent to those skilled in the art that a variety of modifications and changes may be made without departing from the scope of the present invention which is intended to be defined by the appended claims.

What is claimed is:

1. A package module with an offset stacked device, comprising:
a carrier having a first surface and a second surface opposite said first surface, said first surface having a recess and an edge around said recess to allow a first chip arrangement region that is formed in said recess and a plurality of first metal connections is disposed on a bottom of said recess, such that a first recess wall is disposed between said first platform and said first chip arrangement region and said plurality of first metal connections is exposed, a height of said first platform is higher than that of said first chip arrangement region, a plurality of second metal connections is disposed on said first platform, wherein each said plurality of first metal connections is electrically connected with each said plurality of second metal connections by a plurality of first metal wires;
a first chip having a top and a bottom and a plurality of first pads is disposed on said bottom of said first chip, said first chip is flipped on said first chip arrangement region and said plurality of first pads is electrically connected with said plurality of first metal connections;
a second chip having a top and a bottom and a plurality of second pads is disposed on said bottom of said second chip, said second chip is flipped on said top of said first chip such that said plurality of second pads is electrically connected with said plurality of second metal connections on said platform and portion of said top of said first chip is exposed; and
a glue is filled in said recess to encapsulate said top of said first chip and said top of said second chip;
wherein each said plurality of second metal connections is further electrically connected with a plurality of second metal wires, said plurality of second metal wires is disposed from said first platform of said carrier to extend said edge of said first surface, and a third metal connection is formed on one end of said edge of said first surface of each said plurality of second metal wires.

2. The package module with offset stacked device according to claim 1, said package module with the offset stacked device further comprising a substrate which having a third surface and a fourth surface opposites said third surface, and said substrate having a plurality of through holes that is passed through from said third surface to said fourth surface, said third surface having a plurality of electric connections thereon and said fourth surface having a plurality of outer connections thereon, each said plurality of electric connections is passed through said plurality of through holes of said substrate and is extended to said fourth surface and is electrically connected with one of said plurality of outer connections, wherein said third surface of said substrate is stacked on said first surface of said carrier and said plurality of electric connections is electrically connected with one of said plurality of third metal connections of said first surface.

3. The package module with offset stacked device according to claim 1, wherein said package module with offset stacked device further comprising a substrate, said substrate having a third surface and a fourth surface opposites to said third surface, and said substrate having a plurality of through holes which is passed through said third surface to said fourth surface, said third surface having a plurality of electric connections thereon and said fourth surface having a plurality of outer connections thereon, each said plurality of electric connections is extended from said plurality of through holes and fan-out to a peripheral of said fourth surface and is further electrically connected with each one of said plurality of outer connections, wherein said third surface of said substrate is stacked on said first surface of said carrier and said plurality of electric connections is electrically connected with one of said plurality of third metal connections of said first surface.

4. The package module with offset stacked device according to claim 1, wherein an angle between said first recess wall and said first chip arrangement region is in range from 90 degree to 135 degree.

5. A package module with an offset stacked device, comprising:
a carrier having a first surface and a second surface opposites to said first surface, said first surface having a recess, a first chip arrangement region is disposed in said recess and a plurality of first metal connections is disposed on a bottom of said recess, a first platform is disposed on one side of said first chip arrangement region to allow a first recess wall is disposed between said first platform and said first chip arrangement region and said plurality of first metal connections is exposed, and a height of said first platform is higher than that of said first chip arrangement region, a plurality of second metal connections is disposed on said first platform, wherein each said plurality of first metal connections is corresponding to one of said plurality of second metal connections and corresponded said first metal connection is electrically connected with said second metal connections by a first metal wire;
a first chip having a top and a bottom, and a plurality of first pads is disposed on said bottom of said first chip, said first chip is flipped on said first chip arrangement region such that said plurality of first pads is electrically connected with said plurality of first metal connections;
a second chip having a top and a bottom and a plurality of second pads is disposed on said bottom of said second chip, said second chip is flipped on said top of said first chip such that said plurality of second pads is electrically connected with said plurality of metal connections on said first platform and portion said top of said first chip is exposed; and
a glue is filled in said recess of said carrier to encapsulate said top of said first chip and said top of said second chip,
wherein portion of said plurality of first metal connections is further electrically connected with a plurality of second metal wires and remaining said plurality of second metal connections is electrically connected with said plurality of first metal connections which is further electrically connected with a plurality of third metal wires, each said plurality of second metal wires extended from said first chip arrangement region to said edge of said first surface, said plurality of metal wires on one end of said edge is to form a plurality of third metal connections, and each said plurality of metal wires is extended from said first platform to said edge of said first surface and said plurality of third metal wire on one end of said edge of said first surface is to form a plurality of fourth metal connections.

6. The package module with the offset stacked device according to claim 5, wherein said package module with offset stacked device further comprising a substrate, said substrate having a third surface and a fourth surface opposites to said third surface, said substrate having a plurality of through holes and is passed through from said third surface to said fourth surface, said third surface having a plurality of electric connections thereon and said fourth surface having a plurality of outer connections thereon, and each said plurality of electric connections is passed through said plurality of through holes of said substrate and extended to said fourth surface and is electrically connected with one of said plurality of outer connections, wherein said third surface of said substrate is stacked on said first surface of said carrier and said plurality of electric connections is electrically connected with one of said plurality of third metal connections and said plurality of fourth metal connections on said first surface.

7. The package module with the offset stacked device according to claim 5, wherein an angle between said first recess wall and said first chip arrangement region is in range from 90 degree to 135 degree.

8. A package module with an offset stacked device, comprising:
a carrier having a first surface and a second surface opposites to said first surface, said first surface having a recess and an edge around said recess, a first chip arrangement region is disposed in said recess and a plurality of first metal connections is disposed on a bottom of said recess, a first platform is disposed on one side of said first chip arrangement region and said plurality of first metal connections is exposed, a height of said first platform is higher than that of said first chip arrangement region and a first recess wall is disposed between said first platform and said first chip arrangement region so as to an angle between said first recess wall and said first chip arrangement region is in range from 90 degree to 135 degree, a second recess is disposed between said first surface and said first platform so as to an angle between said second recess wall and said first platform is in range from 90 degree to 135 degree, a third recess wall is disposed between said edge and said first chip arrangement region so as to an angle between said third recess and said first chip arrangement region is in range from 90 degree to 135 degree, a plurality of second metal connections is disposed on said first platform, wherein each said plurality of first metal connections is corresponding to one of said plurality of metal connections and corresponded said plurality of first metal connections is electrically connected with corresponded said plurality of second metal connections by a plurality of first metal wires, and said plurality of first metal wires is disposed on said first recess wall;
a first chip having a top and a bottom, a plurality of first pads on said bottom of said first chip and said first chip is flipped on said first chip arrangement region to allow said plurality of pads that is electrically connected with said plurality of first metal connections;
a second chip having a top and a bottom and a plurality of second pads on said bottom of said second chip and said second chip is flipped on said top of said first chip to allow said second plurality of second pads is electrically connected with said plurality of second metal connections on said first platform and portion said top of said first chip is exposed;
a glue is filled in said recess of said carrier to encapsulate said top of said first chip and said top of said second chip,
wherein said plurality of second metal connections is further electrically connected with said plurality of second metal wires and said plurality of second metal wires is extended from said first platform of said carrier to said edge of said first surface and one end of each said plurality of second metal connections on said first surface is to form a third metal connections.

9. The package module with the offset stacked device according to claim 8, wherein said package module with said offset stacked device further comprising a substrate, said substrate having a third surface and a fourth surface opposite to said third surface, and said substrate having a plurality of through holes which is passed through said third surface to said fourth surface, said third surface having a plurality of electric connections thereon and said fourth surface having a plurality of outer connections thereon, each said plurality of electric connections is extended through said plurality of through holes to said fourth surface and is electrically connected with one of said plurality of outer connections, wherein said third surface of said substrate is stacked on said first surface of said carrier and said plurality of electric connections is electrically connected with one of said plurality of third metal connections on said first surface.
